(19) United States
(12) Patent Application Publication
(10) Pub. No.: US 2018/0368269 A1
(43) Pub. Date: Dec. 20, 2018

(54) METHOD AND APPARATUS FOR MANUFACTURING ELECTRONIC COMPOSITE PANELS

(71) Applicant: The Boeing Company, Chicago, IL (US)

(72) Inventors: Scott Robert Johnston, St. Louis, MO (US); Timothy John Franklin Luchini, Berkeley, MO (US)

(21) Appl. No.: 15/627,383

(22) Filed: Jun. 19, 2017

(51) Int. Cl. H05K 3/46; B29C 51/10; H05K 1/02; H05K 3/12; H05K 1/03

(52) U.S. Cl. CPC H05K 3/4644; B29C 51/10; B29K 2079/085; H05K 3/12; H05K 1/0353; H05K 1/028

(57) ABSTRACT

A method and apparatus for manufacturing a composite structure having integrated electronics. A flexible electronic substrate is heated with the flexible electronic substrate positioned relative to a composite laminate. A vacuum is applied to cause the flexible electronic substrate to conform to and bond to the composite laminate, thereby forming an electronic composite panel.

### BACKGROUND INFORMATION

### 1. Field

The present disclosure relates generally to composite structures. More particularly, the present disclosure relates to a method and apparatus for manufacturing composite panels that have integrated electronic circuitry.

### 2. Background

Adding electronic circuitry into composite structures may allow composite structures to be used in a variety of applications. Currently, electronic circuits may be manufactured directly on a composite structure. For example, without limitation, wires, sensors, and other electronic components may need to be directly bonded or attached to a composite structure.

However, in certain environments, the adhesives and bonding materials that are used to attach electronic components to a composite structure may not perform as desired and may result in these electronic components detaching from the composite structure. In some cases, one or more electronic components of an electronic circuit detaching from a composite structure may cause the entire electronic circuit to stop performing. Therefore, it would be desirable to have a method and apparatus that take into account at least some of the issues discussed above, as well as other possible issues.

### SUMMARY

In one illustrative embodiment, a method is provided for manufacturing a composite structure having integrated electronics. A flexible electronic substrate is heated with the flexible electronic substrate positioned relative to a composite laminate. A vacuum is applied to cause the flexible electronic substrate to conform to and bond to the composite laminate, thereby forming an electronic composite panel.

In another illustrative embodiment, a method is provided for manufacturing an electronic composite panel. Electronic circuitry is printed onto a thermoplastic substrate to form a flexible electronic substrate. The flexible electronic substrate is thermoformed to a composite laminate such that the flexible electronic substrate substantially conforms to a contour of the composite laminate.

In yet another illustrative embodiment, a system comprises a thermoforming machine, a flexible electronic substrate, and a composite laminate. The thermoforming machine has a vacuum mold and a substrate holder. The flexible electronic substrate is held by the substrate holder of the thermoforming machine. The composite laminate is laid up over the vacuum fold. The thermoforming machine heats the flexible electronic substrate and applies a vacuum to cause the flexible electronic substrate to conform to and bond to the composite laminate, thereby forming an electronic composite panel.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is an illustration of a thermoforming machine in the form of a block diagram in accordance with an illustrative embodiment;

FIG. 2 is an illustration of a manufacturing environment in accordance with an illustrative embodiment;

FIG. 3 is an illustration of a process for manufacturing a composite structure in the form of a flowchart in accordance with an illustrative embodiment;

FIG. 4 is an illustration of a process for forming an electronic composite panel in the form of a flowchart in accordance with an illustrative embodiment;

FIG. 5 is an illustration of a process for forming an electronic composite panel in the form of a flowchart in accordance with an illustrative embodiment;

FIG. 6 is an illustration of an aircraft manufacturing and service method in the form of a flowchart in accordance with an illustrative embodiment; and

FIG. 7 is an illustration of an aircraft in the form of a block diagram in accordance with an illustrative embodiment.

### DETAILED DESCRIPTION

The illustrative embodiments recognize and take into account different considerations. For example, the illustrative embodiments recognize and take into account that it may be desirable to have a method and apparatus for quickly and easily manufacturing composite structures with integrated electronic circuitry. In particular, the illustrative embodiments recognize and take into account that it may be desirable to bond a thermoplastic substrate with printed electronic circuitry to a composite laminate using a single automated heating and forming process.

Thus, the illustrative embodiments provide a method and apparatus for manufacturing a composite structure having integrated electronics. In one illustrative embodiment, a flexible electronic substrate is heated with the flexible electronic substrate positioned relative to a composite laminate. A vacuum is applied to cause the flexible electronic substrate to conform to and bond to the composite laminate, thereby forming an electronic composite panel.

The process described above may be used to more quickly and easily manufacture complexly contoured composite lamina structures with integrated electronic circuitry. Further, this process may reduce the overall time needed to form composite structures. In particular, this process may provide reduced component handling, faster production of structural components with embedded electronics, and improved part quality. Additionally, with the process described above, fewer tooling fixtures may be needed for providing proper alignment.

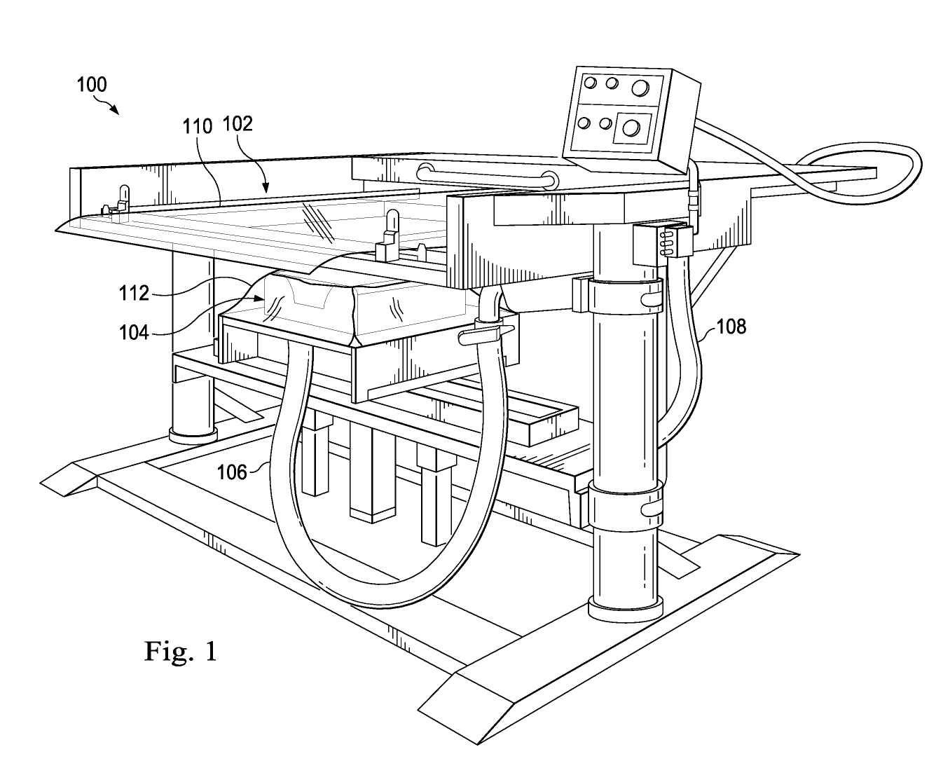

Referring now to the figures and, in particular, with reference to FIG. 1, an illustration of a thermoforming machine is depicted in accordance with an illustrative embodiment. Thermoforming machine 100 may be used to manufacture an electronic composite panel (not shown). The electronic composite panel may be a composite lamina structure with integrated electronic circuitry.

As depicted, thermoforming machine 100 includes substrate holder 102, vacuum mold 104, vacuum system 106, and heater 108. Substrate holder 102 is used to hold flexible electronic substrate 110. In one illustrative example, flexible electronic substrate 110 is a thermoplastic substrate having electronic circuitry (not shown) printed on the thermoplastic substrate in this illustrative example. In one illustrative example, the thermoplastic substrate may be comprised of polyetherimide (PEI).

Composite laminate 112 may be laid up on vacuum mold 104. In one illustrative example, composite laminate 112 has a complexly contoured surface.

Heater 108 may be used to heat flexible electronic substrate 110 while flexile electronic substrate 110 is being held by substrate holder 102. In particular, without limitation, heater 108 may heat flexible electronic substrate 110 to make more pliable. For example, in some cases, flexible electronic substrate 110 is heated to make flexible electronic substrate 110 semi-molten.

In one illustrative example, thermoforming machine 100 may raise vacuum mold 104 up towards flexible electronic substrate 110 such that composite laminate 112 over vacuum mold 104 is made to contact flexible electronic substrate 110. In particular, vacuum mold 104 is raised up into the heated and more pliable flexible electronic substrate 110.

Vacuum system 106 applies a vacuum that allows flexible electronic substrate 110 to substantially conform to the contour of composite laminate 112 over vacuum mold 104. This vacuum may be held for a period of time sufficient to ensure that the flexible electronic substrate 110 bonds to composite laminate 112. Bonding flexible electronic substrate 110 to composite laminate 112 forms an electronic composite panel. This electronic composite panel may then be cured.

Thus, using thermoforming machine 100 and a thermoplastic substrate having integrated printed electronic circuitry allows the bonding of flexible electronic substrate 110 to composite laminate 112 to be performed in a single automated process. This type of process allows the integration of electronic circuitry with composite structures to be performed much more quickly and easily.

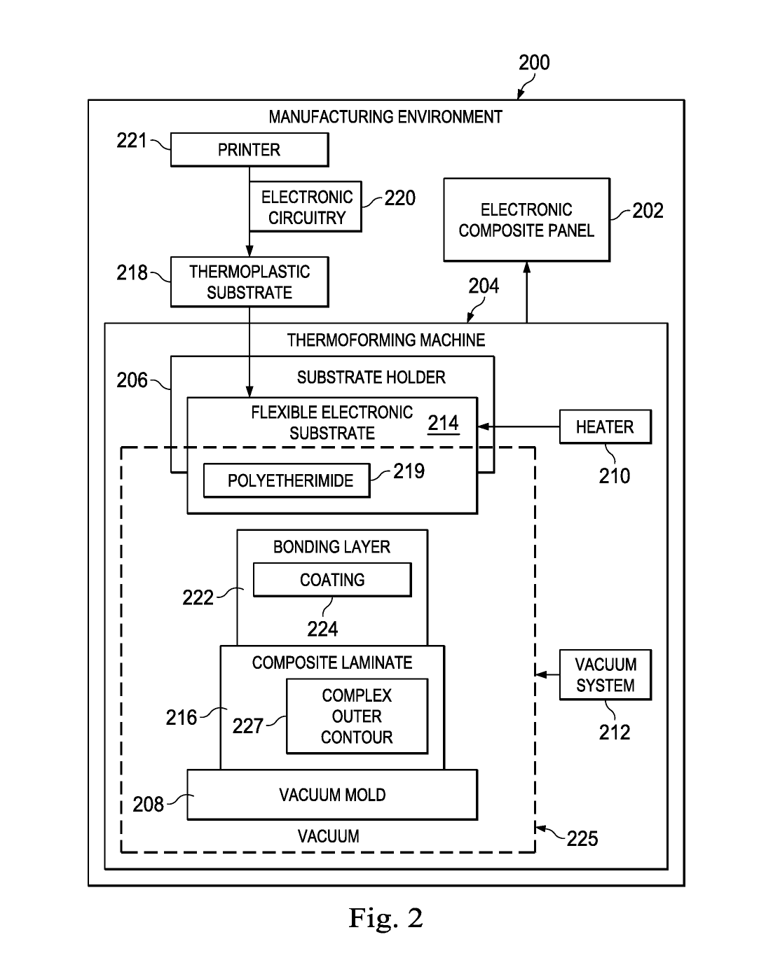

With reference now to FIG. 2, an illustration of a manufacturing environment is depicted in the form of a block diagram in accordance with an illustrative embodiment. Manufacturing environment 200 is an example of one environment in which electronic composite panel 202 may be manufactured. Electronic composite panel 202 may be manufactured using thermoforming machine 204. Thermoforming machine 100 in FIG. 1 is an example of one implementation for thermoforming machine 204.

As depicted, thermoforming machine 204 includes substrate holder 206, vacuum mold 208, heater 210, and vacuum system 212. Substrate holder 102, vacuum mold 104, heater 108, and vacuum system 106 in FIG. 1 may be examples of implementations for substrate holder 206, vacuum mold 208, heater 210, and vacuum system 212, respectively.

Electronic composite panel 202 is formed from flexible electronic substrate 214 and composite laminate 216. Flexible electronic substrate 110 and composite laminate 112 may be examples of implementations for flexible electronic substrate 214 and composite laminate 216, respectively.

In this illustrative example, flexible electronic substrate 110 comprises thermoplastic substrate 218 that has electronic circuitry 220 printed onto thermoplastic substrate 218. Thermoplastic substrate 218 may be comprised of a number of different types of thermoplastic materials. In one illustrative example, thermoplastic substrate 218 is comprised of polyetherimide (PEI) 219. In other illustrative examples, thermoplastic substrate 218 may be comprised of polyester, polycarbonate, polypropylene, polyphenylene sulfide, some other type of material, or a combination thereof.

Electronic circuitry 220 may be applied onto (e.g., by a direct write process) thermoplastic substrate 218 using printer 221. For example, without limitation, printer 221 may use an additive manufacturing process to 3D-print electronic circuitry 220 onto thermoplastic substrate 218. Depending on the implementation, electronic circuitry 220 may be screen printed onto thermoplastic substrate 218, direct-written onto thermoplastic substrate 218, or printed in some other manner. Using 3D-printing to form flexible electronic substrate 214 may help reduce the overall cost of manufacturing electronic composite panel 202.

Electronic circuitry 220 may comprise any number of components. For example, without limitation, electronic circuitry 220 may include at least one of an electronic component, a conductive wire, an electronic trace, or some other type of component. An electronic component may be a resistor, a capacitor, an inductor, a voltage source, or some other type of electronic component.

In one illustrative example, electronic circuitry 220 may be comprised solely of one or more electronic traces. Ink-based materials or some other type of conductive material may be directly written onto thermoplastic substrate 218 to form these electronic traces.

As used herein, the phrase “at least one of,” when used with a list of items, means different combinations of one or more of the listed items may be used and only one of the items in the list may be needed. The item may be a particular object, thing, step, operation, process, or category. In other words, “at least one of” means any combination of items or number of items may be used from the list, but not all of the items in the list may be required.

For example, without limitation, “at least one of item A, item B, or item C” or “at least one of item A, item B, and item C” may mean item A; item A and item B; item B; item A, item B, and item C; item B and item C; or item A and C. In some cases, “at least one of item A, item B, or item C” or “at least one of item A, item B, and item C” may mean, but is not limited to, two of item A, one of item B, and ten of item C; four of item B and seven of item C; or some other suitable combination.

Flexible electronic substrate 214 may be placed in thermoforming machine 204. For example, substrate holder 206 may be used to hold flexible electronic substrate 214 in place.

Composite laminate 216 may be a composite prepreg laminate. In some illustrative examples, composite laminate 216 may be complexly contoured. In other words, in these examples, composite laminate 216 may have a complex outer contour 227. Composite laminate 216 is laid up over vacuum mold 208.

Heater 210 is used to heat flexible electronic substrate 214 while flexible electronic substrate 214 is being held in place by substrate holder 206. Heater 210 heats flexible electronic substrate 214 to a temperature that makes flexible electronic substrate 214 more pliable without melting flexible electronic substrate 214. For example, without limitation, heater 210 may heat flexible electronic substrate 214 until flexible electronic substrate 214 becomes semi-molten. Heater 210 may heat flexible electronic substrate 214 to a temperature between, for example, about 250 degrees Fahrenheit and about 400 degrees Fahrenheit.

Once flexible electronic substrate 214 has become sufficiently pliable, thermoforming machine 204 raises vacuum mold 208 up towards flexible electronic substrate 214. In particular, thermoforming machine 204 may raise vacuum mold 208 such that composite laminate 216 is raised into the heated flexible electronic substrate 214.

Vacuum system 212 applies a vacuum to cause the heated flexible electronic substrate 214 to substantially conform to contour 227 of composite laminate 216. This vacuum may be maintained for a period of time sufficient to ensure that flexible electronic substrate 214 bonds to composite laminate 216. Once flexible electronic substrate 214 has been bonded to composite laminate 216, electronic composite panel 202 is formed. In some illustrative examples, an autoclave, an oven, or some other type of apparatus may be used to cure electronic composite panel 202.

In some illustrative examples, bonding layer 222 may be created over composite laminate 216 prior to the bonding process. Bonding layer 222 may be used to improve bonding between flexible electronic substrate 214 and composite laminate 216. For example, without limitation, in some cases, thermoplastic substrate 218 and composite laminate 216 may be comprised of materials that are unable to bond together during the thermoforming process. Bonding layer 222 is used to help indirectly bond thermoplastic substrate 218 and composite laminate 216.

In one illustrative example, bonding layer 222 is created by applying coating 224 to composite laminate 216. Coating 224 may be, for example, without limitation, an adhesive material that is selected because the adhesive material can bond to both thermoplastic substrate 218 and composite laminate 216.

When bonding layer 222 is present, raising vacuum mold 208 with composite laminate 216 into heated flexible electronic substrate 214, while the vacuum is being applied, causes flexible electronic substrate 214 to bond to bonding layer 222. In this manner, flexible electronic substrate 214 may be indirectly bonded to composite laminate 216.

Thus, the illustrative embodiments provide a method and apparatus for manufacturing composite lamina structures with integrated electronic circuitry. The processes described above may be used to speed up overall production times and reduce manufacturing costs.

Electronic composite panel 202 that is formed may be used in a variety of applications. For example, electronic circuitry 220 on electronic composite panel 202 may be used as a light emitting diode, an antenna, or a de-icing trace.

The illustration in FIG. 2 is not meant to imply physical or architectural limitations to the manner in which an illustrative embodiment may be implemented. Other components in addition to or in place of the ones illustrated may be used. Some components may be optional. Also, the blocks are presented to illustrate some functional components. One or more of these blocks may be combined, divided, or combined and divided into different blocks when implemented in an illustrative embodiment.

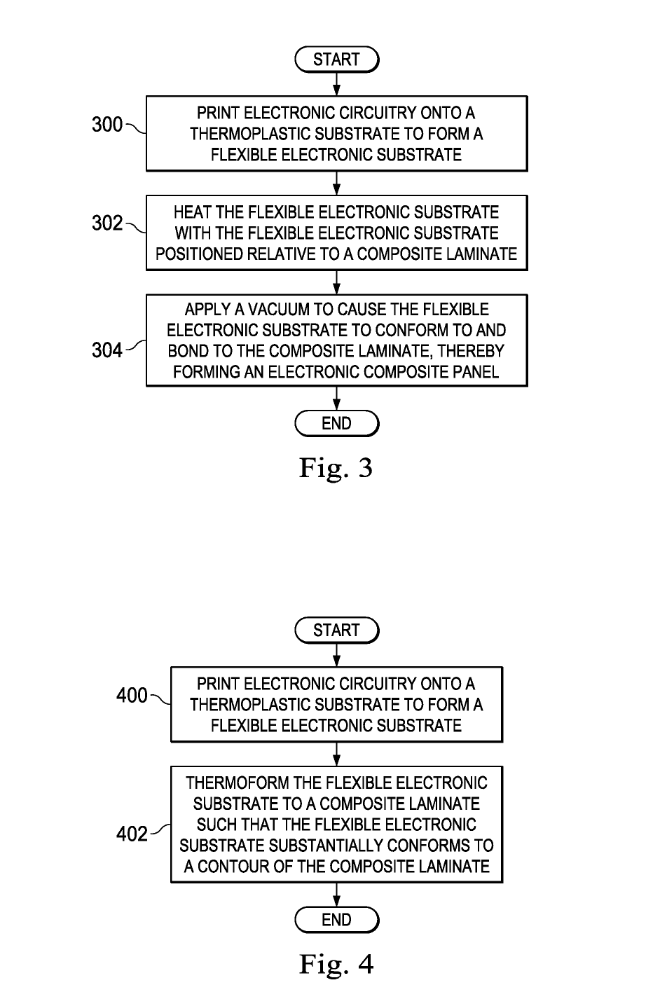

With reference now to FIG. 3, an illustration of a process for manufacturing a composite structure is depicted in the form of a flowchart in accordance with an illustrative embodiment. The process illustrated in FIG. 3 may be implemented using thermoforming machine 100 in FIG. 1 or thermoforming machine 204 described in FIG. 2 to manufacture electronic composite panel 202 in FIG. 2.

The process begins by printing electronic circuitry onto a thermoplastic substrate to form a flexible electronic substrate (operation 300). Thereafter, the flexible electronic substrate is heated with the flexible electronic substrate positioned relative to a composite laminate (operation 302). In operation 300, the flexible electronic substrate may be held in place within the thermoforming machine over a vacuum mold over which the composite laminate is laid up.

A vacuum is applied to cause the flexible electronic substrate to conform to and bond to the composite laminate, thereby forming an electronic composite panel (operation 304), with the process terminating thereafter. The steps of heating and applying the vacuum may be together referred to as a thermoforming process.

With reference now to FIG. 4, an illustration of a process for forming an electronic composite panel is depicted in the form of a flowchart in accordance with an illustrative embodiment. The process illustrated in FIG. 4 may be implemented using thermoforming machine 100 in FIG. 1 or thermoforming machine 204 described in FIG. 2 to manufacture electronic composite panel 202 in FIG. 2.

The process may begin by printing electronic circuitry onto a thermoplastic substrate to form a flexible electronic substrate (operation 400). Next, the flexible electronic substrate is thermoformed to a composite laminate such that the flexible electronic substrate substantially conforms to a contour of the composite laminate (operation 402), with the process terminating thereafter.

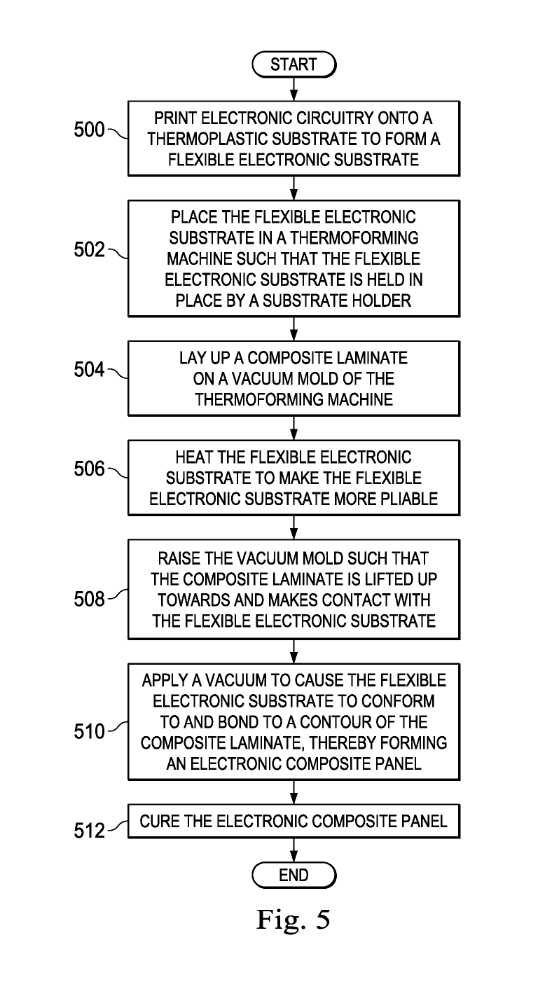

With reference now to FIG. 5, an illustration of a process for forming an electronic composite panel is depicted in the form of a flowchart in accordance with an illustrative embodiment. The process illustrated in FIG. 5 may be implemented using thermoforming machine 100 in FIG. 1 or thermoforming machine 204 described in FIG. 2 to manufacture electronic composite panel 202 in FIG. 2.

The process may begin by printing electronic circuitry onto a thermoplastic substrate to form a flexible electronic substrate (operation 500). The flexible electronic substrate is placed in a thermoforming machine such that the flexible electronic substrate is held in place by a substrate holder (operation 502). A composite laminate is laid up on a vacuum mold of the thermoforming machine (operation 504).

Thereafter, the flexible electronic substrate is heated to make the flexible electronic substrate more pliable (operation 506). In operation 506, the flexible electronic substrate may be made semi-molten. Specifically, the flexible electronic substrate may be heated to make the flexible electronic substrate more pliable. Next, the vacuum mold is raised such that the composite laminate is lifted up towards and makes contact with the composite laminate into the flexible electronic substrate (operation 508). A vacuum is applied to cause the flexible electronic substrate to conform to and bond to a contour of the composite laminate, thereby forming an electronic composite panel (operation 510). The electronic composite panel may then be cured (operation 512) with the process terminating thereafter.

The flowcharts and block diagrams in the different depicted embodiments illustrate the design, architecture, and functionality of some possible implementations of apparatuses and methods in an illustrative embodiment. In this regard, each block in the flowcharts or block diagrams may represent a module, a segment, a function, and/or a portion of an operation or step.

In some alternative implementations of an illustrative embodiment, the function or functions noted in the blocks may occur out of the order noted in the figures. For example, in some cases, two blocks shown in succession may be executed substantially concurrently, or the blocks may sometimes be performed in the reverse order, depending upon the functionality involved. Also, other blocks may be added in addition to the illustrated blocks in a flowchart or block diagram.

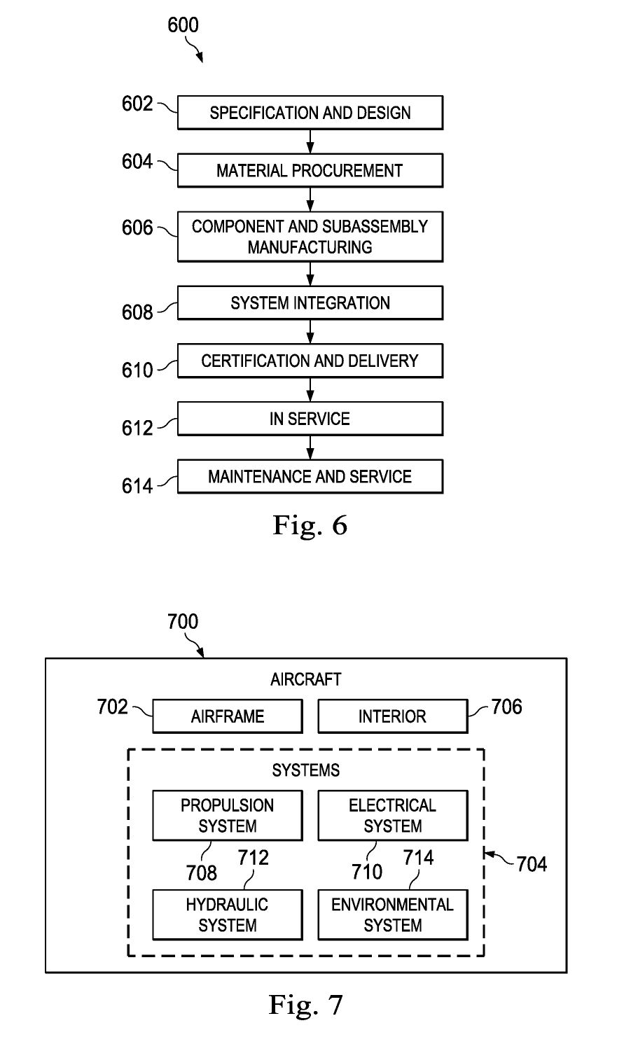

Illustrative embodiments of the disclosure may be described in the context of aircraft manufacturing and service method 600 as shown in FIG. 6 and aircraft 700 as shown in FIG. 7. Turning first to FIG. 6, a flowchart of an aircraft manufacturing and service method is depicted in accordance with an illustrative embodiment. During pre-production, aircraft manufacturing and service method 600 may include specification and design 602 of aircraft 700 in FIG. 7 and material procurement 604.

During production, component and subassembly manufacturing 606 and system integration 608 of aircraft 700 in FIG. 7 takes place. Thereafter, aircraft 700 in FIG. 7 may go through certification and delivery 610 in order to be placed in service 612. While in service 612 by a customer, aircraft 700 in FIG. 7 is scheduled for routine maintenance and service 614, which may include modification, repair, refurbishment, and other maintenance or service.

Each of the processes of aircraft manufacturing and service method 600 may be performed or carried out by a system integrator, a third party, and/or an operator. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 7, a block diagram of an aircraft is depicted in which an illustrative embodiment may be implemented. In this example, aircraft 700 is produced by aircraft manufacturing and service method 600 in FIG. 6 and may include airframe 702 with plurality of systems 704 and interior 706. Examples of systems 704 include one or more of propulsion system 708, electrical system 710, hydraulic system 712, and environmental system 714. Any number of other systems may be included. Although an aerospace example is shown, different illustrative embodiments may be applied to other industries, such as the automotive industry.

Apparatuses and methods embodied herein may be employed during at least one of the stages of aircraft manufacturing and service method 600 in FIG. 6. In particular, the method and apparatus for forming an electronic composite panel as described in FIGS. 1-2 may be used during any one of the stages of aircraft manufacturing and service method 600. For example, without limitation, electronic composite panels may be manufactured using the methodology described by the illustrative embodiments use in the fabrication during at least one of specification and design 602, material procurement 604, component and subassembly manufacturing 606, system integration 608, routine maintenance and service 614, or some other stage of aircraft manufacturing and service method 600. Further, these electronic composite panels may be used to build any number of parts, sub-parts, or systems for aircraft 700.

In one illustrative example, components or subassemblies produced in component and subassembly manufacturing 606 in FIG. 6 may be fabricated or manufactured in a manner similar to components or subassemblies produced while aircraft 700 is in service 612 in FIG. 6. As yet another example, one or more apparatus embodiments, method embodiments, or a combination thereof may be utilized during production stages, such as component and subassembly manufacturing 606 and system integration 608 in FIG. 6. One or more apparatus embodiments, method embodiments, or a combination thereof may be utilized while aircraft 700 is in service 612 and/or during maintenance and service 614 in FIG. 6. The use of a number of the different illustrative embodiments may substantially expedite the assembly of and/or reduce the cost of aircraft 700.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method for manufacturing a composite structure having integrated electronics, the method comprising:
heating (302) a flexible electronic substrate (110, 214) with the flexible electronic substrate positioned relative to a composite laminate (112, 216); and
applying (304) a vacuum (225) to cause the flexible electronic substrate to conform to and bond to the composite laminate, thereby forming an electronic composite panel (202).

2. The method of claim 1 further comprising:
creating a bonding layer (222) over the composite laminate.

3. The method of claim 2, wherein creating the bonding layer comprises:
applying a coating (224) of adhesive material over the composite laminate.

4. The method of claim 2 further comprising:
positioning the flexible electronic substrate relative to the bonding layer.

5. The method of claim 4, wherein applying the vacuum comprises:
applying the vacuum to cause the flexible electronic substrate to conform to and bond to the bonding layer and to cause the bonding layer to bond to the composite laminate, thereby indirectly bonding the flexible electronic substrate to the composite laminate.

6. The method of claim 1, wherein heating the flexible electronic substrate comprises:
heating the flexible electronic substrate using a thermoforming machine (100, 204) to make the flexible electronic substrate more pliable, wherein the flexible electronic substrate comprises a thermoplastic substrate (218) with electronic circuitry (220) applied onto the thermoplastic substrate by a direct write process.

7. The method of claim 1, wherein applying the vacuum comprises:
maintaining the vacuum for a period of time to enable bonding between the flexible electronic substrate and the composite laminate.

8. The method of claim 1 further comprising:
curing (512) the electronic composite panel.

9. The method of claim 1 further comprising:
laying up (504) the composite laminate over a vacuum mold (104, 208) to form a composite layup.

10. The method of claim 1 further comprising:
printing (500) electronic circuitry (220) onto a thermoplastic substrate (218), wherein the thermoplastic substrate is comprised of polyetherimide and wherein the electronic circuitry comprises an electronic component, a conductive wire, or an electronic trace.

11. A method for manufacturing an electronic composite panel (202), the method comprising:
printing (400) electronic circuitry (220) onto a thermoplastic substrate (218) to form a flexible electronic substrate (110, 214); and
thermoforming (402) the flexible electronic substrate to a composite laminate (112, 216) such that the flexible electronic substrate substantially conforms to a contour (227) of the composite laminate and forms an electronic composite panel.

12. The method of claim 11 further comprising:
curing the electronic composite panel.

13. A system comprising:
a thermoforming machine (100, 204) having a vacuum mold (104, 208) and a substrate holder (102, 206);
a flexible electronic substrate (110, 214) that is held by the substrate holder of the thermoforming machine; and
a composite laminate (112, 216) laid up over the vacuum mold,
wherein the thermoforming machine heats the flexible electronic substrate and applies a vacuum (225) to cause the flexible electronic substrate to conform to and bond to the composite laminate, thereby forming an electronic composite panel (202).

14. The system of claim 13, wherein the flexible electronic substrate comprises a thermoplastic substrate (218) having electronic circuitry (220) applied onto the thermoplastic substrate by a direct write process.

15. The system of claim 14, wherein the thermoplastic substrate comprises at least one of polyetherimide, polyester, polycarbonate, polypropylene, or polyphenylene sulfide.

16. The system of claim 13 further comprising:
a bonding layer (222) created over the composite laminate by applying a coating (224) of adhesive material over the composite laminate.

17. The system of claim 16, wherein applying the vacuum causes the flexible electronic substrate to conform to and bond to the bonding layer and causes the bonding layer to bond to the composite laminate, thereby indirectly bonding the flexible electronic substrate to the composite laminate.

18. The system of claim 13 further comprising:
an oven for curing the electronic composite panel.

19. The system of claim 13 further comprising:
a printer (221) for applying, by a direct write process, electronic circuitry (220) onto a thermoplastic substrate (218) to form the flexible electronic substrate.

20. The system of claim 13, wherein the flexible electronic substrate comprises electronic circuitry (220) that includes an electronic component, a conductive wire, or an electronic trace.
